(19) United States
(12) Patent Application Publication
(10) Pub. No.: US 2026/0078301 A1
(43) Pub. Date: Mar. 19, 2026

(54) COMPOSITIONS, RELATED SYSTEMS, AND RELATED METHODS OF REMOVING METAL OXIDES

(71) Applicant: ENTEGRIS, INC., Billerica, MA (US)

(72) Inventors: Hsing-Chen Wu, Hsinchu City (TW); Ming-Chi Liao, Taoyuan City (TW); Min-Chieh Yang, Hsinchu City (TW)

(21) Appl. No.: 19/326,577

(22) Filed: Sep. 11, 2025

Related U.S. Application Data
(60) Provisional application No. 63/694,706, filed on Sep. 13, 2024.

(51) Int. Cl. C09K 13/08

(52) U.S. Cl. CPC C09K 13/08

(57) ABSTRACT

Composition, related systems and methods of removing metal oxides from a structure. The composition comprises 10% to 25% by weight of an ammonium fluoride based on a total weight of the composition. The composition comprises 0.1% to 1% by weight of a hydrogen fluoride based on a total weight of the composition. The composition comprises 0.1% to 1% by weight of a nitride inhibitor based on a total weight of the composition. When the composition contacts a structure comprising a silicon nitride surface and a metal oxide surface, the composition selectively etches the metal oxide surface.

### CROSS-REFERENCE TO RELATED APPLICATIONS

This application claims the benefit under 35 USC 119 of U.S. Provisional Patent Application No. 63/694,706, filed Sep. 13, 2024, the disclosure of which is hereby incorporated herein by reference in its entirety.

### FIELD

The present disclosure relates to compositions, related systems, and related methods of removing metal oxides.

### BACKGROUND

Conventional buffer etch solutions provide a high and stable etch rate for oxide layer removal but may damage silicon nitride layers.

### SUMMARY

Some embodiments relate to a composition. In some embodiments, the composition comprises 10% to 25% by weight of an ammonium fluoride based on a total weight of the composition. In some embodiments, the composition comprises 0.1% to 1% by weight of a hydrogen fluoride based on a total weight of the composition. In some embodiments, the composition comprises 0.1% to 1% by weight of a nitride inhibitor based on a total weight of the composition. In some embodiments, when the composition contacts a structure comprising a silicon nitride surface and a metal oxide surface, the composition selectively etches the metal oxide surface.

Some embodiments relate to a method. In some embodiments, the method comprises the following steps: obtaining a composition, contacting a structure with the composition, and selectively etching at least a portion of the metal oxide surface from the structure. In some embodiments, the structure comprises a non-dielectric material, and a dielectric material. In some embodiments, the composition comprises 10% to 25% by weight of an ammonium fluoride based on a total weight of the composition. In some embodiments, the composition comprises 0.1% to 1% by weight of a hydrogen fluoride based on a total weight of the composition. In some embodiments, the composition comprises 0.1% to 1% by weight of a nitride inhibitor based on a total weight of the composition. In some embodiments, the structure comprises a silicon nitride surface and a metal oxide surface.

### DRAWINGS

FIG. 1 is a flowchart of a method of removing metal oxides from a structure, according to some embodiments.

### DETAILED DESCRIPTION

Among those benefits and improvements that have been disclosed, other objects and advantages of this disclosure will become apparent from the following description taken in conjunction with the accompanying FIGURES. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Formation of a nanosheet structure requires the removal of the silicon germanium (SiGe) layers in the Si/SiGe stacking. In the formation of the nanosheet structure, the stacking SiGe layers may be replaced by a recessed oxide inner space layer. The recessed oxide inner space layer must be removed without the removal of the silicon nitride (SiN) inner spacers. The SiN inner spacers are needed to support the nanosheet structure. Some embodiments provided herein overcome at least these challenges by providing compositions, systems, and related methods for the selective removal of oxide layers.

Some embodiments relate to a composition. In some embodiments the composition comprises at least one of an ammonium fluoride, a hydrogen fluoride, a nitride inhibitor, or any combination thereof. In some embodiments, the composition is a buffer oxide etch (BOE) based etching solution with a high oxide etch rate and high selectivity to SiN.

In some embodiments, the composition comprises 10% to 25% by weight of an ammonium fluoride based on a total weight of the composition, or any range or subrange between 10% and 25%. In some embodiments, for example, the ammonium fluoride based on a total weight of the composition may be 11% to 24%, 12% to 23%, 13% to 22%, 14% to 21%, 15% to 20%, 16% to 19%, or 17% to 18%. In some embodiments, the ammonium fluoride based on a total weight of the composition may be 11% to 25%, 12% to 25%, 13% to 25%, 14% to 25%, 15% to 25%, 16% to 25%, 17% to 25%, 18% to 25%, 19% to 25%, 20% to 25%, 21% to 25%, 22% to 25%, 23% to 25%, or 24% to 25%. In some embodiments, the ammonium fluoride based on a total weight of the composition may be 10% to 24%, 10% to 23%, 10% to 22%, 10% to 21%, 10% to 20%, 10% to 19%, 10% to 18%, 10% to 17%, 10% to 16%, 10% to 15%, 10% to 14%, 10% to 13%, 10% to 12%, or 10% to 11%.

In some embodiments, the composition comprises 15% to 20% by weight of the ammonium fluoride based on a total weight of the composition, or any range or subrange between 15% and 20%. In some embodiments, the ammonium fluoride based on a total weight of the composition may be 16% to 20%, 17% to 20%, 18% to 20%, or 19% to 20%. In some embodiments, the ammonium fluoride based on a total weight of the composition may be 15% to 19%, 15% to 18%, 15% to 17%, or 15% to 16%.

In some embodiments, the ammonium fluoride in the composition may be present in an amount that does not affect the etch rate of a metal oxide surface.

In some embodiments, the composition comprises 0.1% to 1% by weight of a hydrogen fluoride based on a total weight of the composition, or any range or subrange between 0.1% and 1%. In some embodiments, the hydrogen fluoride based on a total weight of the composition may be 0.2% to 0.9%, 0.3% to 0.8%, 0.4% to 0.7%, or 0.5% to 0.6%. In some embodiments, the hydrogen fluoride based on a total weight of the composition may be 0.2% to 1%, 0.3% to 1%, 0.4% to 1%, 0.5% to 1%, 0.6% to 1%, 0.7% to 1%, 0.8% to 1%, or 0.9% to 1%. In some embodiments, the hydrogen fluoride based on a total weight of the composition may be 0.1% to 0.9%, 0.1% to 0.8%, 0.1% to 0.7%, 0.1% to 0.6%, 0.1% to 0.5%, 0.1% to 0.4%, 0.1% to 0.3%, or 0.1% to 0.2%.

In some embodiments, the composition comprises 0.1% to 0.3% by weight of the hydrogen fluoride based on a total weight of the composition, or any range or subrange between 0.1% and 0.3%.

In some embodiments, the composition comprises a nitride inhibitor. In some embodiments, the nitride inhibitor comprises at least one of a polyacryl acid, an imidazole, a piperazine, a 2-picolinic acid, a nicotinic acid, a DL-Proline, a L-Glutamic acid, a Dodecylbenzene sulfonic acid, or any combination thereof.

In some embodiments, the composition comprises 0.1% to 1% by weight of a nitride inhibitor based on a total weight of the composition, or any range or subrange between 0.1% and 1%. In some embodiments, the nitride inhibitor based on a total weight of the composition may be 0.2% to 0.9%, 0.3% to 0.8%, 0.4% to 0.7%, or 0.5% to 0.6%. In some embodiments, the nitride inhibitor based on a total weight of the composition may be 0.2% to 1%, 0.3% to 1%, 0.4% to 1%, 0.5% to 1%, 0.6% to 1%, 0.7% to 1%, 0.8% to 1%, or 0.9% to 1%. In some embodiments, the nitride inhibitor based on a total weight of the composition may be 0.1% to 0.9%, 0.1% to 0.8%, 0.1% to 0.7%, 0.1% to 0.6%, 0.1% to 0.5%, 0.1% to 0.4%, 0.1% to 0.3%, or 0.1% to 0.2%.

In some embodiments, when the composition contacts a structure comprising a silicon nitride surface and a metal oxide surface, the composition selectively etches the metal oxide surface. In some embodiments, the metal oxide surface comprises silicon oxide.

In some embodiments, the composition further comprises a solvent. In some embodiments, the solvent is selected from the group consisting of methanol, ethanol, isopropanol, butanol, pentanol, hexanol, 2-ethyl-1-hexanol, heptanol, octanol, ethylene glycol, propylene glycol, butylene glycol, butylene carbonate, ethylene carbonate, propylene carbonate, dipropylene glycol, diethylene glycol, diethylene glycol monomethyl ether, triethylene glycol monomethyl ether, diethylene glycol monoethyl ether, triethylene glycol monoethyl ether, ethylene glycol monopropyl ether, ethylene glycol monobutyl ether, diethylene glycol monobutyl ether, triethylene glycol monobutyl ether, ethylene glycol monohexyl ether, diethylene glycol monohexyl ether, ethylene glycol phenyl ether, propylene glycol methyl ether, dipropylene glycol methyl ether (DPGME), tripropylene glycol methyl ether (TPGME), dipropylene glycol dimethyl ether, dipropylene glycol ethyl ether, propylene glycol n-propyl ether, dipropylene glycol n-propyl ether (DPGPE), tripropylene glycol n-propyl ether, propylene glycol n-butyl ether, dipropylene glycol n-butyl ether, tripropylene glycol n-butyl ether, propylene glycol phenyl ether, 2,3-dihydrodecafluoropentane, ethyl perfluorobutylether, methyl perfluorobutylether, dimethyl sulfoxide (DMSO), sulfolane, 4-methyl-2-pentanol, diethylene glycol diethyl ether, diethylene glycol ethyl methyl ether, 3-methyl-2-oxazolidone, N-methylmorpholine N-oxide, trimethylamine N-oxide and combinations thereof.

In some embodiments, the solvent comprises an organic solvent. In some embodiments, the organic solvent comprises at least one species selected from the group consisting of a glycol ether (e.g., diethylene glycol monomethyl ether, diethylene glycol monoethyl ether, diethylene glycol monobutyl ether), DMSO, sulfolane, methanesulfonic acid, or combinations thereof. In some embodiments, the solvent comprises n-octylacetate.

In some embodiments, the composition further comprises 0.1% to 20% by weight of a solvent based on a total weight of the composition, or any range or subrange between 0.1% and 20%. In some embodiments, for example, the solvent based on a total weight of the composition may be 0.5% to 19%, 1% to 18%, 2% to 17%, 3% to 16%, 4% to 15%, 5% to 14%, 6% to 13%, 7% to 12%, 8% to 11%, or 9% to 10%. In some embodiments, the solvent based on a total weight of the composition may be 0.5% to 20%, 1% to 20%, 2% to 20%, 4% to 20%, 6% to 20%, 8% to 20%, 10% to 20%, 12% to 20%, 14% to 20%, 16% to 20%, or 18% to 20%. In some embodiments, for example, the solvent based on a total weight of the composition may be 0.1% to 18%, 0.1% to 16%, 0.1% to 14%, 0.1% to 12%, 0.1% to 10%, 0.1% to 8%, 0.1% to 6%, 0.1% to 4%, 0.1% to 2%, 0.1% to 1%, or 0.1% to 0.5%.

In some embodiments, the composition further comprises a surfactant. In some embodiments, the surfactant comprises disulfonic acid. As used herein, the term “disulfonic acid” refers to a compound comprising sulfonic acid. In some embodiments, a sulfonic acid is an acid of the formula: —S(═O)(═O) OH. In some embodiments, a disulfonic acid comprises a compound of the formula: HO(O═)₂S—R—S(═O)₂OH, where R is an alkyl or an aryl, as defined herein. In some embodiments, R comprises a heteroatom, such as, for example and without limitation, at least one of O, N, S, or any combination thereof, and the like. Non-limiting examples of disulfonic acids include, for example and without limitation, at least one of a C₁₂ branched diphenyl oxide disulfonic acid, methanedisulfonic acid, ethanedisulfonic acid, 1,3-propanedisulfonic acid, or any combination thereof.

In some embodiments, the composition comprises 0.1 ppm to 150 ppm of a surfactant, or any range or subrange between 0.1 ppm and 150 ppm. In some embodiments, for example, the surfactant in the composition may be 0.5 ppm to 100 ppm, 1 ppm to 50 ppm, or 10 ppm to 25 ppm. In some embodiments, the surfactant in the composition may be 0.5 ppm to 150 ppm, 1 ppm to 150 ppm, 10 ppm to 150 ppm, 50 ppm to 150 ppm, or 100 ppm to 150 ppm. In some embodiments, the surfactant in the composition may be 0.1 ppm to 100 ppm, 0.1 ppm to 50 ppm, 0.1 ppm to 25 ppm, or 0.1 ppm to 10 ppm.

In some embodiments, the composition comprises a water. In some embodiments, the water comprises a deionized water.

In some embodiments, at least one of the ammonium fluoride, the hydrogen fluoride, the nitride inhibitor, or any combination thereof is present in an amount sufficient for the composition, when used for etching a structure, so as to increase selectivity of a metal oxide layer of the structure relative to a conventional buffer oxide etch solution.

In some embodiments, the selectivity of the metal oxide/SiN may be 300 to 800, or any range or subrange between 300 and 800. In some embodiments, the selectivity of the metal oxide/SiN may be 350 to 750, 400 to 700, 450 to 650, or 500 to 600. In some embodiments, the selectivity of the metal oxide/SiN may be 350 to 800, 400 to 800, 450 to 800, 500 to 800, 550 to 800, 600 to 800, 650 to 800, 700 to 800, or 750 to 800. In some embodiments, the selectivity of the metal oxide/SiN may be 300 to 750, 300 to 700, 300 to 650, 300 to 600, 300 to 550, 300 to 500, 300 to 450, 300 to 400, or 300 to 350.

In some embodiments, the selectivity of the metal oxide/SiN may be greater than 400.

In some embodiments, the ammonium fluoride, the hydrogen fluoride, and the nitride inhibitor, and the water are present in an amount sufficient for the composition, when used for etching a structure, so as to increase an etch rate of metal oxide layer of the structure relative to the conventional buffer oxide etch solution. In some embodiments, the hydrogen fluoride may increase the etch rate of the silicon oxide surface by 1% to 99%, or any range or subrange between 1% and 99%. In some embodiments, for example, the hydrogen fluoride may increase the etch rate of the metal oxide surface by 5% to 95%, 10% to 90%, 15% to 85%, 20% to 80%, 25% to 75%, 30% to 70%, 35% to 65%, 40% to 60%, or 45% to 55%. In some embodiments, for example, the hydrogen fluoride may increase the etch rate of the silicon oxide surface by 5% to 99%, 10% to 99%, 15% to 99%, 20% to 99%, 25% to 99%, 30% to 99%, 35% to 99%, 40% to 99%, 45% to 99%, 50% to 99%, 55% to 99%, 60% to 99%, 65% to 99%, 70% to 99%, 75% to 99%, 80% to 99%, 85% to 99%, 90% to 99%, or 95% to 99%. In some embodiments, for example, the hydrogen fluoride may increase the etch rate of the metal oxide surface by 1% to 95%, 1% to 90%, 1% to 85%, 1% to 80%, 1% to 75%, 1% to 70%, 1% to 65%, 1% to 60%, 1% to 55%, 1% to 50%, 1% to 45%, 1% to 40%, 1% to 35%, 1% to 30%, 1% to 25%, 1% to 20%, 1% to 15%, 1% to 10%, or 1% to 5%.

In some embodiments, the composition further comprises a defoaming agent. The defoaming agent may reduce foam during the etching process. The nitride inhibitor in the composition may create the foam. Non-limiting examples of the defoaming agent include, for example and without limitation, at least one of an alkyl carbamate compound, a bicarbonate compound, a sulfuric acid compound, or any combination thereof. In some embodiments, the defoaming agent comprises an alkyl carbamate. In some embodiments, the defoaming agent comprises a bicarbonate compound. In some embodiments, the defoaming agent comprises a sulfuric acid compound.

In some embodiments, the composition further comprises pH adjuster. The pH adjuster may be capable of adjusting the pH of the composition. The pH of the compositions may be adjusted using any suitable compound capable of adjusting the pH of the composition. The pH adjuster may be water-soluble and compatible with the other components of the composition. In some embodiments, the pH adjuster comprises at least one of an inorganic acid, a metal salt, an organic acid, an organic hydroxide, or any combination thereof. In some embodiments, the metal salt comprises at least one of a metal nitrate, a metal hydroxide, or any combination thereof. In some embodiments, the pH adjuster comprises at least one of H₂SO₄, HNO₃, HF, H₃PO₄, HCl, Al(NO₃)₃, Mn(NO₃)₂, Zr(NO₃)₂, Fe(NO₃)₃, KOH, NaOH, Al(OH)₃, CH₃SO₃H, polystyrene sulfonic acid (PSSA), toluenesulfonic acid, salicylic acid, oxalic acid, succinic acid, citric acid, malic acid, lactic acid, fumaric acid, NH₄OH, choline hydroxide, or any combination thereof.

Typically, the composition has a pH of 0 to 14, or any range or subrange between 0 and 14. In some embodiments, for example, the composition has a pH of 1 to 13, 2 to 12, 3 to 11, 4 to 10, 5 to 9, or 6 to 8. In some embodiments, the composition has a pH of 1 to 14, 2 to 14, 3 to 14, 4 to 14, 5 to 14, 6 to 14, 7 to 14, 8 to 14, 9 to 14, 10 to 14, 11 to 14, 12 to 14, or 13 to 14. In some embodiments, for example, the composition has a pH of 1 to 13, 2 to 12, 3 to 11, 4 to 10, 5 to 9, or 6 to 8. In some embodiments, the composition has a pH of 0 to 13, 0 to 12, 0 to 11, 0 to 10, 0 to 9, 0 to 8, 0 to 7, 0 to 6, 0 to 5, 0 to 4, 0 to 3, 0 to 2, or 0 to 1.

In some embodiments, the composition has a pH of 0 to 7, 1 to 6, 2 to 5, or 3 to 4. In some embodiments, the composition has a pH of 1 to 7, 2 to 7, 3 to 7, 4 to 7, 5 to 7, or 6 to 7. In some embodiments, the composition has a pH of 0 to 6, 0 to 5, 0 to 4, 0 to 3, 0 to 2, or 0 to 1.

In some embodiments, the composition has a pH of 8 to 14, 9 to 13, or 10 to 12. In some embodiments, the composition has a pH of 8 to 13, 8 to 12, 8 to 11, 8 to 10, or 8 to 9. In some embodiments, the composition has a pH of 9 to 14, 10 to 14, 11 to 14, 12 to 14, or 13 to 14.

Some embodiments relate to a system. In some embodiments, the system comprises a composition. It will be appreciated that any one or more of the compositions disclosed herein may be employed, without departing from the scope of this disclosure. For example, in some embodiments, the composition comprises 15% to 20% by weight of the ammonium fluoride based on a total weight of the composition. In some embodiments, the composition comprises 0.1% to 0.3% by weight of the hydrogen fluoride based on a total weight of the composition.

In some embodiments, the system comprises a structure. In some embodiments the structure comprises a non-dielectric material and a dielectric material.

The structure may comprise a non-dielectric material. In some embodiments, the non-dielectric material comprises a semiconductor material. In some embodiments, the non-dielectric material comprises a semiconductor layer. In some embodiments, the semiconductor layer is a single layer, a crystalline layer, or any combination thereof. In some embodiments, the non-dielectric material comprises at least one of the non-dielectric material comprises at least one of a silicon (Si), a germanium (Ge), a silicon germanium (SiGe), a gallium arsenide (GaAs), an indium antimonide (InSb), a gallium phosphide (GaP), a gallium antimonide (GaSb), a indium aluminum arsenide (InAlAs), a indium gallium arsenide (InGaAs), a gallium antimony phosphide (GaSbP), a gallium arsenic antimonide (GaAsSb), a indium phosphide (InP), or any combination thereof. In some embodiments, the non-dielectric material comprises silicon. In some embodiments, the non-dielectric material comprises polysilicon.

The structure may comprise a non-dielectric material. In some embodiments, the non-dielectric material is proximate to the dielectric material. In some embodiments, the non-dielectric material is a non-dielectric layer. In some embodiments, the non-dielectric material is a non-dielectric feature. In some embodiments, the non-dielectric material is a non-dielectric structure. In some embodiments, the non-dielectric material is a non-dielectric spacer. In some embodiments, the non-dielectric material comprises a semiconductor material. In some embodiments, the non-dielectric material comprises a conducting material. In some embodiments, the non-dielectric material is polycrystalline. In some embodiments, the non-dielectric material is amorphous. In some embodiments, the non-dielectric material is an epitaxial semiconductor material. In some embodiments, the non-dielectric material comprises molybdenum silicide. In some embodiments, the non-dielectric material comprises a metal. In some embodiments, the non-dielectric material comprises a metal nitride.

The structure may comprise a dielectric material. In some embodiments, the dielectric material is a dielectric layer. In some embodiments, the dielectric material is a dielectric feature. In some embodiments, the dielectric material is a dielectric structure. In some embodiments, the dielectric material comprises at least one of HfO₂, ZrO₂, HfAlOₓ, HfSiOₓ, Al₂O₃, SiCN, SiOC, SiOCN, or any combination thereof.

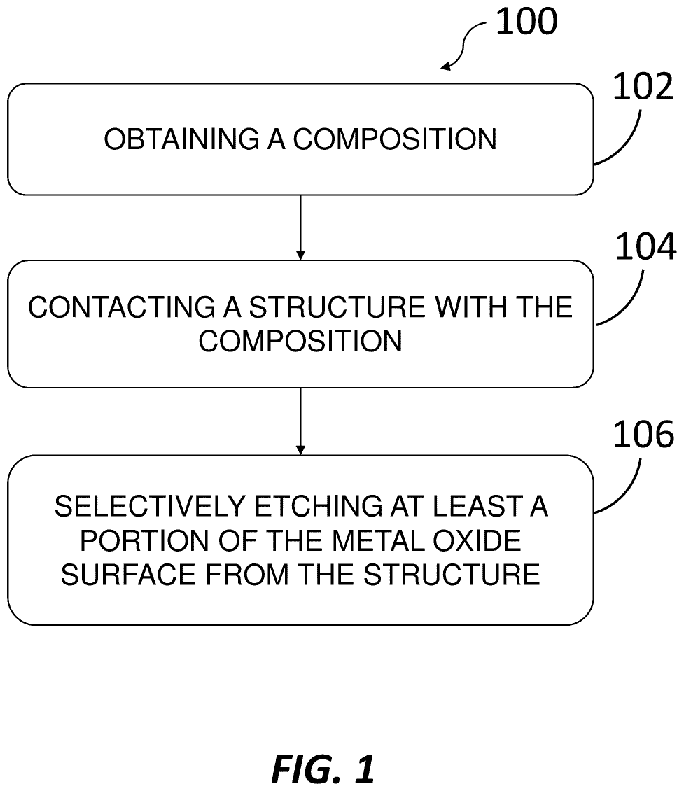

FIG. 1 is a flowchart of a method of removing metal oxides from a structure, according to some embodiments. As shown in FIG. 1, the method of removing metal oxides from a structure may comprise one or more of the following steps: obtaining a composition; contacting a structure with a composition; and selectively etching at least a portion of the metal oxide surface from the structure.

At step 102, in some embodiments, the method comprises obtaining a composition. In some embodiments, the composition is the composition described herein. In some embodiments, the composition comprises 10% to 25% by weight of an ammonium fluoride based on a total weight of the composition. In some embodiments, the composition comprises 0.1% to 1% by weight of a hydrogen fluoride based on a total weight of the composition. In some embodiments, the composition comprises 0.1% to 1% by weight of a nitride inhibitor based on a total weight of the composition.

In some embodiments, the composition further comprises a defoaming agent. In some embodiments, wherein the composition further comprises a pH adjuster. In some embodiments, wherein the composition further comprises a solvent. In some embodiments, wherein the composition further comprises a water.

In some embodiments, the composition comprises 15% to 20% by weight of the ammonium fluoride based on a total weight of the composition. In some embodiments, the composition comprises 0.1% to 0.3% by weight of the hydrogen fluoride based on a total weight of the composition.

At step 104, in some embodiments, the method comprises contacting a structure with the composition. In some embodiments, the structure comprises a silicon nitride surface and a metal oxide surface as described herein. In some embodiments, the metal oxide surface comprises silicon oxide.

At step 106, in some embodiments, the method comprises selectively etching at least a portion of the metal oxide surface from the structure.

The step of contacting the structure with the composition may be under conditions sufficient to selectively etching at least a portion of the metal oxide surface. In some embodiments, the step of contacting the structure with the composition may be under the conditions sufficient to deposit a metal oxide layer on at least a portion of the non-dielectric material. In some embodiments, the step of contacting the structure with the composition may be under the conditions sufficient to form a SiN inner spacer on at least a portion of the non-dielectric material. In some embodiments, the contacting of the structure with the composition exhibits a selectivity for the non-dielectric material over the dielectric material.

In some embodiments, the composition comprises the composition disclosed herein. In some embodiments, the composition comprises at least one of an ammonium fluoride, a hydrogen fluoride, a nitride inhibitor, or any combination thereof.

Any one or more of the embodiments disclosed herein shall be understood to be combinable without departing from the scope or spirit of the disclosure.

### Example 1

Various compositions for removal of metal oxides were prepared and the performance of each was compared. DIW is Deionized Water. AF is ammonium Fluoride. All samples were prepared as reported in Table 1 and Table 2 below:

TABLE 1
Composition
Composition by weight percentage based on the total composition

| | | | | 0.5% N-Octyl |
|---|---|---|---|---|
| Sample | DIW | 40% AF | 1% HF | acetate |
| 1 | 50 | | 50 | |
| 2 | 44.7 | 40 | 7.35 | 6 |
| 3 | 45.7 | 40 | 7.35 | 6 |
| 4 | 45.7 | 40 | 7.35 | 6 |
| 5 | 45.7 | 40 | 7.35 | 6 |
| 6 | 45.7 | 40 | 7.35 | 6 |
| 7 | 45.7 | 40 | 7.35 | 6 |
| 8 | 45.7 | 40 | 7.35 | 6 |
| 9 | 46.6 | 40 | 7.35 | 6 |

TABLE 2
Composition
Composition by weight percentage based on the total composition
Nitride Inhibitors

| Polyacryl | | | 2-Picolinic | Nicotinic | | L-Glutamic | Dodecylbenzene |
|---|---|---|---|---|---|---|---|
| acid 50% aq | Imidazole | Piperazine | acid | Acid | DL-Proline | acid | sulfonic acid |
| 2 | | | | | | | |
| | 1 | | | | | | |
| | | 1 | | | | | |
| | | | 1 | | | | |
| | | | | 1 | | | |
| | | | | | 1 | | |
| | | | | | | 1 | |
| | | | | | | | 0.05 |

TABLE 3
Results

| No. | Oxide ER | SiN ER | Selectivity |
|---|---|---|---|
| Sample | E/R (Å/min) | E/R (Å/min) | Ox/SiN |
| 1 | 371.2 | 10.12 | 36.7 |
| 2 | 985.4 | 4.07 | 242.1 |
| 3 | −4.1 | 0.78 | −5.3 |
| 4 | −9.3 | 0.37 | −25.2 |
| 5 | 511.8 | 4.41 | 116.0 |
| 6 | 537.7 | 4.40 | 122.1 |
| 7 | 205.3 | 2.93 | 70.0 |
| 8 | 477.6 | 4.24 | 112.6 |
| 9 | 426.2 | 3.80 | 112.2 |

The compositions were optimized for hydrogen fluoride and ammonium fluoride. Compositions comprising Polyacryl acid and Nicotinic acid had higher SiN etch rates and higher oxide selectivity.

### Example 2

Various compositions for removal of metal oxides were prepared and the performance of each was compared. All samples were prepared as reported in Table 4 below:

TABLE 4
Composition
Composition by weight percentage based on the total composition

| | BOE solution | | | | Nitride Inhibitors | | |
|---|---|---|---|---|---|---|---|
| | | Ammonium | | 0.5% N-Octyl | Polyacryl | 2-Picolinic | Nicotinic |
| No. | DIW | fluoride | 1% HF | DIW acetate | acid 50% aq | acid | Acid |
| 10 | 72.65 | 12 | 7.35 | 6 | 2 | | |
| 11 | 70.20 | 12 | 9.80 | 6 | 2 | | |
| 12 | 67.75 | 12 | 12.25 | 6 | 2 | | |
| 13 | 65.3 | 12 | 14.70 | 6 | 2 | | |
| 14 | 66.3 | 12 | 14.70 | 6 | | 0.5 | 0.5 |

TABLE 5
Results

| | Temp. | oxide | SiN | Selectivity |
|---|---|---|---|---|
| No. | ° C. | E/R (Å/min) | E/R (Å/min) | Ox/SiN |
| 10 | 25 | 929.9 | 3.142 | 296 |
| 11 | 25 | 943.1 | 3.312 | 285 |
| 12 | 25 | 1213.8 | 3.720 | 326 |
| 13 | 25 | 1467.3 | 3.598 | 408 |
| 14 | 25 | 999.6 | 4.818 | 207 |

The compositions were optimized for ammonium fluoride. Compositions with an increased weight percentage of hydrogen fluoride and Polyacryl acid had higher SiO etch rates and higher oxide selectivity.

### Example 3

Various compositions for removal of metal oxides were prepared and the performance of each was compared. All samples were prepared as reported in Table 6 below:

TABLE 6
Composition
Composition by weight percentage based on the total composition

| | BOE solution | | | | Nitride Inhibitors | |
|---|---|---|---|---|---|---|
| | | Ammonium | | 0.5% N-Octyl | Polyacryl | Nicotinic |
| | | fluoride | 1% HF | acetate DIW | acid 50% aq | Acid |
| | | CAS No. | | | | |
| No. | DIW | 12125-01-8 | | | 9003-01-4 | 59-67-6 |
| 15 | 69.3 | 8 | 14.7 | 6 | 2 | |
| 16 | 73.3 | 4 | 14.7 | 6 | 2 | |
| 17 | 65.4 | 18 | 19.6 | 6 | | 1 |
| 18 | 69.4 | 4 | 19.6 | 6 | | 1 |

TABLE 7
Results

| | Temp. | oxide | SiN | Selectivity |
|---|---|---|---|---|
| No. | ° C. | E/R (Å/min) | E/R (Å/min) | Ox/SiN |
| 15 | 25 | 1458.9 | 3.56 | 410 |
| 16 | 25 | 866.0 | 3.19 | 272 |
| 17 | 25 | 1320.6 | 5.42 | 244 |
| 18 | 25 | 1025.8 | 5.46 | 188 |

The compositions were optimized for both ammonium fluoride and hydrogen fluoride. Compositions comprising an increased weight percentage of ammonium fluoride and a decreased weight percentage of hydrogen fluoride with polyacryl acid, had higher SiO etch rates and higher oxide selectivity. Additionally, the data showed that a reduced weight percentage of ammonium fluoride in a composition will not significantly affect the etch rate. However, there is weight percentage below which the oxide etch rate may significantly drop.

In some embodiments, the formulation had a silicon oxide etch rate of greater than 800 angstroms per minute. Some embodiments included greater than 1000 angstroms per minute etch rates of silicon oxide. These embodiments were able to achieve a selectivity of at least 150 angstroms etched of silicon oxide per angstrom etched of silicon nitride. Some embodiments achieved 180, 200, 220, 240, or 400 or greater selectivity. As shown in Table 7, high etch rates could be achieved while maintaining excellent selectivity. The silicon oxide and silicon nitride in some embodiments was substantially pure with minimal other elements incorporated.

### Aspects

Various Aspects are described below. It is to be understood that any one or more of the features recited in the following Aspect(s) can be combined with any one or more other Aspect(s).

Aspect 1. A composition comprising:
10% to 25% by weight of an ammonium fluoride based on a total weight of the composition;
0.1% to 1% by weight of a hydrogen fluoride based on a total weight of the composition; and
0.1% to 1% by weight of a nitride inhibitor based on a total weight of the composition,
   wherein, when the composition contacts a structure comprising a silicon nitride surface and a metal oxide or metalloid oxide surface, the composition selectively etches the metal oxide or metalloid oxide surface.

Aspect 2. The composition according to Aspect 1, wherein the composition further comprises a defoaming agent.

Aspect 3. The composition according to any one of Aspects 1-2, wherein the composition further comprises a pH adjuster.

Aspect 4. The composition according to any one of Aspects 1-3, wherein the composition further comprises a solvent.

Aspect 5. The composition according to any one of Aspects 1-4, wherein the composition further comprises a water.

Aspect 6. The composition according to any one of Aspects 1-5, wherein the composition comprises 15% to 20% by weight of the ammonium fluoride based on a total weight of the composition.

Aspect 7. The composition according to any one of Aspects 1-6, wherein the solvent comprises an organic solvent.

Aspect 8. The composition according to any one of Aspects 1-7, wherein the composition comprises 0.1% to 0.3% by weight of the hydrogen fluoride based on a total weight of the composition.

Aspect 9. The composition according to any one of Aspects 1-8, wherein the nitride inhibitor comprises at least one of a polyacryl acid, an imidazole, a piperazine, a 2-picolinic acid, a nicotinic acid, a DL-Proline, a L-Glutamic acid, a dodecylbenzene sulfonic acid, or any combination thereof.

Aspect 10. The composition according to any one of Aspects 1-9, wherein the composition comprises 0.1% to 20% by weight of a solvent based on a total weight of the composition.

Aspect 11. The composition according to any one of Aspects 1-10, wherein the composition comprises 0.1 ppm to 150 ppm of a surfactant.

Aspect 12. The composition according to any one of Aspects 1-8, wherein the metal oxide or metalloid oxide surface comprises silicon oxide.

Aspect 13. A method comprising:
obtaining a composition,
   wherein the composition comprises:
      10% to 25% by weight of an ammonium fluoride based on a total weight of the composition,
      0.1% to 1% by weight of a hydrogen fluoride based on a total weight of the composition, and
      0.1% to 1% by weight of a nitride inhibitor based on a total weight of the composition;
contacting a structure with the composition,
   wherein the structure comprises a silicon nitride surface and
   a metal oxide or metalloid oxide surface; and
selectively etching at least a portion of the metal oxide or metalloid oxide surface from the structure.

Aspect 14. The method according to Aspect 13, wherein the metal oxide or metalloid oxide surface comprises silicon oxide.

Aspect 15. The method according to any one of Aspects 13-14, wherein the composition further comprises a defoaming agent.

Aspect 16. The method according to any one of Aspects 13-15, wherein the composition further comprises a pH adjuster.

Aspect 17. The method according to any one of Aspects 13-16, wherein the composition further comprises a solvent.

Aspect 18. The method according to any one of Aspects 13-17, wherein the composition further comprises a water.

Aspect 19. The method according to any one of Aspects 13-18, wherein the composition comprises 15% to 20% by weight of the ammonium fluoride based on a total weight of the composition.

Aspect 20. The method according to any one of Aspects 13-19, wherein the composition comprises 0.1% to 0.3% by weight of the hydrogen fluoride based on a total weight of the composition.

What is claimed is:

1. A composition comprising:
10% to 25% by weight of an ammonium fluoride based on a total weight of the composition;
0.1% to 1% by weight of a hydrogen fluoride based on a total weight of the composition;
0.1% to 1% by weight of a nitride inhibitor based on a total weight of the composition,
wherein, when the composition contacts a structure comprising a silicon nitride surface and a metal oxide or metalloid oxide surface, the composition selectively etches the metal oxide or metalloid oxide surface.

2. The composition of claim 1, wherein the composition further comprises a defoaming agent.

3. The composition of claim 1, wherein the composition further comprises a pH adjuster.

4. The composition of claim 1, wherein the composition further comprises a solvent.

5. The composition of claim 1, wherein the composition further comprises a water.

6. The composition of claim 1, wherein the composition comprises 15% to 20% by weight of the ammonium fluoride based on a total weight of the composition.

7. The composition of claim 4, wherein the solvent comprises an organic solvent.

8. The composition of claim 1, wherein the composition comprises 0.1% to 0.3% by weight of the hydrogen fluoride based on a total weight of the composition.

9. The composition of claim 1, wherein the nitride inhibitor comprises at least one of a polyacryl acid, an imidazole, a piperazine, a 2-picolinic acid, a nicotinic acid, a DL-proline, a L-Glutamic acid, a dodecylbenzene sulfonic acid, or any combination thereof.

10. The composition of claim 4, wherein the composition comprises 0.1% to 20% by weight of the solvent based on a total weight of the composition.

11. The composition of claim 1, wherein the composition comprises 0.1 ppm to 150 ppm of a surfactant.

12. The composition of claim 1, wherein the metal oxide or metalloid oxide surface comprises silicon oxide.

13. A method comprising:
obtaining a composition,
wherein the composition comprises:
10% to 25% by weight of an ammonium fluoride based on a total weight of the composition,
0.1% to 1% by weight of a hydrogen fluoride based on a total weight of the composition, and
0.1% to 1% by weight of a nitride inhibitor based on a total weight of the composition;
contacting a structure with the composition,
wherein the structure comprises a silicon nitride surface and a metal oxide or metalloid oxide surface; and
selectively etching at least a portion of the metal oxide or metalloid oxide surface from the structure.

14. The method of claim 13, wherein the metal oxide or metalloid oxide surface comprises silicon oxide.

15. The method of claim 13, wherein the composition further comprises a defoaming agent.

16. The method of claim 13, wherein the composition further comprises a pH adjuster.

17. The method of claim 13, wherein the composition further comprises a solvent.

18. The method of claim 13, wherein the composition further comprises a water.

19. The method of claim 13, wherein the composition comprises 15% to 20% by weight of the ammonium fluoride based on a total weight of the composition.

20. The method of claim 13, wherein the composition comprises 0.1% to 0.3% by weight of the hydrogen fluoride based on a total weight of the composition.
